(19) United States
(12) Patent Application Publication
(10) Pub. No.: US 2025/0133869 A1
(43) Pub. Date: Apr. 24, 2025

(54) METHOD FOR MANUFACTURING LIGHT-EMITTING DEVICE

(71) Applicant: NICHIA CORPORATION, Anan-shi (JP)

(72) Inventor: Hiroki YUU, Anan-shi (JP)

(73) Assignee: NICHIA CORPORATION, Anan-shi (JP)

(21) Appl. No.: 18/916,707

(22) Filed: Oct. 16, 2024

(30) Foreign Application Priority Data
Oct. 20, 2023 (JP) 2023-180998

(51) Int. Cl. H01L 33/00; H01L 25/075

(52) U.S. Cl. CPC H10H 20/018; H01L 25/0753

(57) ABSTRACT

A method for manufacturing a light-emitting device including providing a first structure having a support substrate, a first bonding member on a surface thereof, and light-emitting elements having a first surface in contact with the first bonding member, an opposite second surface, and electrodes on a second surface side. The method includes providing a second structure having a substrate including a base member and terminal portions on a surface thereof, and a second bonding member between the terminal portions and thicker than the terminal portions. The method includes disposing the first structure on the second bonding member such that respective electrodes and respective terminal portions are spaced apart from and facing each other, connecting the respective electrodes and the respective terminal portions, and after the connecting, exposing the first and second bonding members to a solution to remove them to separate off the support substrate from the light-emitting elements.

### CROSS-REFERENCE TO RELATED APPLICATIONS

The present application claims priority under 35 U.S.C. § 119 to Japanese Patent Application No. 2023-180998, filed Oct. 20, 2023. The contents of this application are incorporated herein by reference in their entirety.

### BACKGROUND

### Technical Field

The present disclosure relates to a method for manufacturing a light-emitting device.

### Background Art

A light-emitting device in which light-emitting elements are mounted on a base member is known. To mount the light-emitting elements on the base member in a manufacturing process of such a light-emitting device, for example, a step of forming a bonding member on the base member, a step of disposing the light-emitting elements on a support substrate to prepare a light-emitting element-mounted support substrate, and a step of disposing the light-emitting element-mounted support substrate on the bonding member such that the light-emitting elements and the bonding member face each other and separating off the support substrate from the light-emitting element-mounted support substrate are performed (for example, see Japanese Patent Application Publication No. 2021-103774 A).

### SUMMARY

It has been determined that a need exists to more reliably separate off a support substrate from light-emitting elements in a method for manufacturing a light-emitting device including light-emitting elements.

A method for manufacturing a light-emitting device according to an embodiment of the present disclosure includes: providing a first structure including a support substrate, a first bonding member disposed on a surface of the support substrate, and a plurality of light-emitting elements each having a first surface and a second surface opposite to the first surface, the first surface being in contact with the first bonding member, each of the light-emitting elements including a plurality of electrodes on a second surface side; providing a second structure including a substrate including a base member and a plurality of terminal portions disposed on a surface of the base member, and a second bonding member being disposed between the plurality of terminal portions on the surface of the base member and being thicker than each of the terminal portions; disposing the first structure on the second bonding member of the second structure such that a respective one of the plurality of electrodes and a respective one of the plurality of terminal portions are spaced apart from each other while facing each other; connecting the respective one of the plurality of electrodes and the respective one of the plurality of terminal portions; and after the connecting, exposing the first bonding member and the second bonding member to a solution to remove the first bonding member and the second bonding member to separate off the support substrate from the plurality of light-emitting elements.

According to embodiments of the present disclosure, in a method for manufacturing a light-emitting device including light-emitting elements, a support substrate can be more reliably separated off from light-emitting elements.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a light-emitting device according to a first embodiment.

FIG. 2A is a view schematically illustrating an example of a manufacturing step of a method for manufacturing a light-emitting device according to the first embodiment.

FIG. 2B is a view schematically illustrating an example of a manufacturing step of the method for manufacturing a light-emitting device according to the first embodiment.

FIG. 2C is a view schematically illustrating an example of the manufacturing step of the method for manufacturing a light-emitting device according to the first embodiment.

FIG. 2D is a view schematically illustrating an example of a manufacturing step of the method for manufacturing a light-emitting device according to the first embodiment.

FIG. 2E is a view schematically illustrating an example of a manufacturing step of the method for manufacturing a light-emitting device according to the first embodiment.

FIG. 2F is a view schematically illustrating an example of a manufacturing step of the method for manufacturing a light-emitting device according to the first embodiment.

FIG. 2G is a view schematically illustrating an example of a manufacturing step of the method for manufacturing a light-emitting device according to the first embodiment.

FIG. 3A is a view schematically illustrating an example of a manufacturing step of a method for manufacturing a light-emitting device according to a second embodiment.

FIG. 3B is a view schematically illustrating an example of a manufacturing step of the method for manufacturing a light-emitting device according to the second embodiment.

FIG. 4A is a view schematically illustrating an example of a manufacturing step of a method for manufacturing a light-emitting device according to a third embodiment.

FIG. 4B is a view schematically illustrating an example of a manufacturing step of the method for manufacturing a light-emitting device according to the third embodiment.

FIG. 4C is a view schematically illustrating an example of a manufacturing step of the method for manufacturing a light-emitting device according to the third embodiment.

FIG. 5A is a view schematically illustrating an example of a manufacturing step of a method for manufacturing a light-emitting device according to a fourth embodiment.

FIG. 5B is a view schematically illustrating an example of a manufacturing step of the method for manufacturing a light-emitting device according to the fourth embodiment.

FIG. 5C is a view schematically illustrating an example of a manufacturing step of the method for manufacturing a light-emitting device according to the fourth embodiment.

FIG. 5D is a view schematically illustrating an example of a manufacturing step of the method for manufacturing a light-emitting device according to the fourth embodiment.

FIG. 5E is a view schematically illustrating an example of a manufacturing step of the method for manufacturing a light-emitting device according to the fourth embodiment.

FIG. 5F is a view schematically illustrating an example of a manufacturing step of the method for manufacturing a light-emitting device according to the fourth embodiment.

### DETAILED DESCRIPTION

Hereinafter, a manufacturing method of an embodiment according to the present disclosure and a light-emitting device obtained by the method of manufacturing (hereinafter, may be referred to as a “light-emitting device according to an embodiment”) are described with reference to the drawings. In the following description, terms indicating a specific direction or position (for example, “upper”, “lower”, and other terms including those terms) are used as necessary. However, the use of those terms is intended to facilitate understanding of the invention with reference to the drawings, and the technical scope of the present disclosure is not limited by the meanings of those terms. Parts having the same reference characters appearing in a plurality of drawings indicate identical or equivalent parts or members.

The following embodiments exemplify a light-emitting device and the like for embodying a technical idea of the present disclosure, and the present disclosure is not limited to the description below. The dimensions, materials, shapes, relative arrangements, and the like of constituent components described below are not intended to limit the scope of the present disclosure to those alone, but are intended to provide an example, unless otherwise specified. The contents described in one embodiment can be applied to any of the other embodiments and modified examples. The sizes, positional relationship, and the like of the members illustrated in the drawings can be exaggerated in order to clarify the explanation. Furthermore, in order to avoid excessive complication of the drawings, a schematic view in which some elements are not illustrated may be used, or an end view illustrating only a cutting surface may be used as a cross-sectional view.

### First Embodiment

### Light-Emitting Device

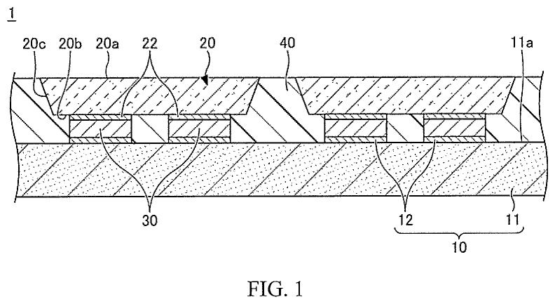

As a premise for describing a method for manufacturing a light-emitting device according to a first embodiment, a configuration example of a light-emitting device 1 is described with reference to FIG. 1. FIG. 1 is a cross-sectional view schematically illustrating the light-emitting device according to the first embodiment. FIG. 1 illustrates a cross-section taken through a first surface of a light-emitting element and a plurality of electrodes. As illustrated in FIG. 1, the light-emitting device 1 according to the first embodiment includes a substrate 10, a plurality of light-emitting elements 20, a plurality of conductive members 30, and a light reflective member 40. The light-emitting device 1 need not include the light reflective member 40. In the light-emitting device 1, the plurality of light-emitting elements 20 are arranged on the substrate 10. For example, the plurality of light-emitting elements 20 are arranged in a matrix on the substrate 10.

The substrate 10 includes a base member 11 having a flat plate shape and a plurality of terminal portions 12 disposed on the base member 11. The plurality of terminal portions 12 are spaced apart from each other on a surface 11a of the base member 11. The light-emitting element 20 has a first surface 20a, a second surface 20b on which a plurality of electrodes 22 are disposed, the second surface 20b being opposite to the first surface 20a, and one or more lateral surfaces 20c connecting the first surface 20a and the second surface 20b.

In each of the light-emitting elements 20, each of the electrodes 22 faces a corresponding one of the terminal portions 12. The plurality of electrodes 22 of each light-emitting element 20 may include an anode-side electrode and a cathode-side electrode, and may include three or more electrodes. The plurality of terminal portions 12 facing the plurality of electrodes 22 of each light-emitting element 20 may include an anode-side terminal portion and a cathode-side terminal portion, and may include three or more terminal portions. Each of the plurality of electrodes 22 of the light-emitting element 20 and a respective one of the plurality of terminal portions 12 of the substrate 10 facing that are electrically connected to each other by a corresponding one of the conductive members 30.

The light reflective member 40 is disposed on the surface 11a of the base member 11 such that the first surface 20a of the light-emitting element 20 is exposed and the light reflective member 40 covers the second surface 20b and the lateral surfaces 20c. The light reflective member 40 may also cover lateral surfaces of the terminal portion 12, lateral surfaces of the electrode 22, and lateral surfaces of the conductive member 30.

With the light reflective member 40 covering the lateral surfaces 20c of the light-emitting element 20, light emitted from the lateral surface 20c of the light-emitting element 20 is reflected by the light reflective member 40. In addition, with the light reflective member 40 covering the second surface 20b of the light-emitting element 20, light traveling downward from the light-emitting element 20 is reflected by the light reflective member 40. Thus, light extraction efficiency in the light-emitting device 1 can be improved. In addition, with the light reflective member 40, when the light-emitting elements 20 are individually lit, the boundary between a light-emitting area and a non-light-emitting area can be clarified. This improves the contrast ratio between the light-emitting area and the non-light-emitting area.

Each of the components of the light-emitting device 1 is described below.

### Substrate 10

The base member 11 has, for example, a substantially rectangular shape in plan view. However, the shape of the base member 11 is not limited thereto. As the base member 11, a transparent base member or an opaque base member may be used. Examples of the material of the transparent base member include glass, quartz, sapphire, ceramics (for example, transparent alumina), and organic films (for example, PET). Examples of the material of the opaque base member include semiconductors (for example, Si, Ge, GaAs, and InP), ceramics (for example, alumina, aluminum nitride, and silicon nitride), and organic materials (for example, FR4).

Examples of the terminal portion 12 include metals such as Cu, Ag, Au, Al, Pt, Ti, W, Pd, Fe, and Ni, and/or alloys containing at least any of these metals. A region of the surface 11a of the base member 11 where the terminal portions 12 are not disposed may or may not be covered with an insulating film.

### Light-Emitting Element

The light-emitting element 20 has, for example, a substantially rectangular shape or a substantially square shape in plan view. However, the shape of the light-emitting element 20 is not limited thereto. In plan view, the shape of the light-emitting element 20 can be a square whose one side is in a range from 40 μm to 100 μm, for example. In the light-emitting element 20, the first surface 20a and the second surface 20b are, for example, parallel to each other. The lateral surface 20c may be perpendicular to the first surface 20a or may be inclined with respect to the first surface 20a. In the example of FIG. 1, the lateral surfaces 20c facing each other are inclined in a direction in which the width between the lateral surfaces 20c becomes narrower from the first surface 20a side toward the second surface 20b side in cross-sectional view.

The light-emitting element 20 includes a semiconductor layered body and positive and negative electrodes 22 disposed on the second surface 20b being a surface of the semiconductor layered body. The light-emitting element 20 is flip-chip mounted on the substrate 10 with the second surface 20b, on which the electrodes 22 are disposed, facing the substrate 10 side. In this case, the first surface 20a opposite to the second surface 20b serves as a main light extraction surface of the light-emitting element 20.

In the light-emitting device 1, the plurality of light-emitting elements 20 may be two-dimensionally arranged in a matrix on the substrate 10. In this case, the light-emitting elements 20 can be arranged in alignment at predetermined intervals in each of the row and column directions. For example, the number of light-emitting elements 20 included in the light-emitting device 1 can be in a range from 100 to 2000000, preferably in a range from 1000 to 500000, more preferably in a range from 3000 to 150000. When the light-emitting device 1 includes 100 or more light-emitting elements, road surface projection including simple messaging or the like can be performed when the light-emitting device 1 is used for road surface projection or the like in in-vehicle headlights. In addition, when the number of light-emitting elements included in the light-emitting device 1 is 2000000 or less, high-definition road surface projection can be implemented, the light-emitting device 1 can be miniaturized, and light with sufficient illuminance can be emitted when each light-emitting element 20 is individually lit.

A light-emitting element that emits light of any appropriate wavelength can be selected as the light-emitting element 20. For example, as the light-emitting elements 20 that emit blue light and green light, light-emitting elements using a nitride semiconductor In_{X}Al_{Y}Ga_{1-X-Y}N (0≤X, 0≤Y, X+Y≤1) can be selected. As the light-emitting element 20 that emits red light, a semiconductor represented by GaAlAs or AlInGaP can be used. Furthermore, a semiconductor light-emitting element made of other material can be used. The composition and light emission color of the light-emitting elements 20 to be used can be selected as appropriate in accordance with an intended purpose.

### Conductive Member

The conductive member 30 can be made of copper (Cu) or gold (Au), for example. The conductive member 30 may be made of zinc (Zn), chromium (Cr), nickel (Ni), and/or the like. The thickness of the conductive member 30 can be in a range from 3 μm to 10 μm, for example.

### Light Reflective Member

For the light reflective member 40, a soft resin having relatively low elasticity and high shape conformability is preferably used. As the material of the light reflective member 40, a resin material having good light-transmittance and insulation properties, for example, a thermosetting resin such as an epoxy-based resin or a silicone-based resin, can be suitably used. Preferably, the light reflective member 40 uses a white resin in which a base resin contains particles of a light reflective material. Examples of the light reflective material include titanium oxide, aluminum oxide, zinc oxide, barium carbonate, barium sulfate, boron nitride, aluminum nitride, and glass filler.

Method for Manufacturing Light-emitting Device according to First Embodiment A method for manufacturing the light-emitting device 1 according to the first embodiment is described below. The method for manufacturing the light-emitting device 1 according to the first embodiment includes: a step of providing a first structure including a support substrate, a first bonding member disposed on a surface of the support substrate, and a plurality of light-emitting elements each having a first surface and a second surface opposite to the first surface, the first surface being in contact with the first bonding member, the light-emitting elements each including a plurality of electrodes disposed on a second surface side; a step of providing a second structure including a substrate and a second bonding member, the substrate including a base member and a plurality of terminal portions disposed on a surface of the base member, the second bonding member being disposed between the plurality of terminal portions on the surface of the base member and being thicker than each of the terminal portions; a step of disposing the first structure on the second bonding member of the second structure such that the plurality of electrodes and the plurality of terminal portions are spaced apart from each other while facing each other; a step of connecting each of the plurality of electrodes and a respective one of the plurality of terminal portions; and after the step of connecting, a step of separating off the support substrate from the plurality of light-emitting elements by exposing the first bonding member and the second bonding member to a solution to remove the first bonding member and the second bonding member.

Each manufacturing step of the method for manufacturing the light-emitting device according to the first embodiment is described below with reference to the drawings.

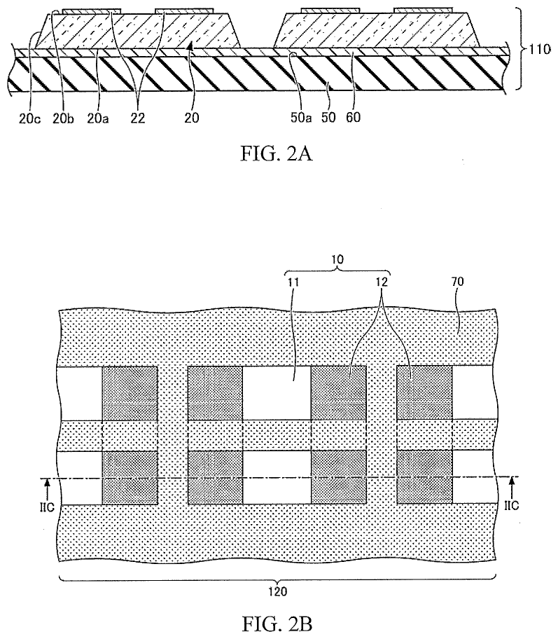

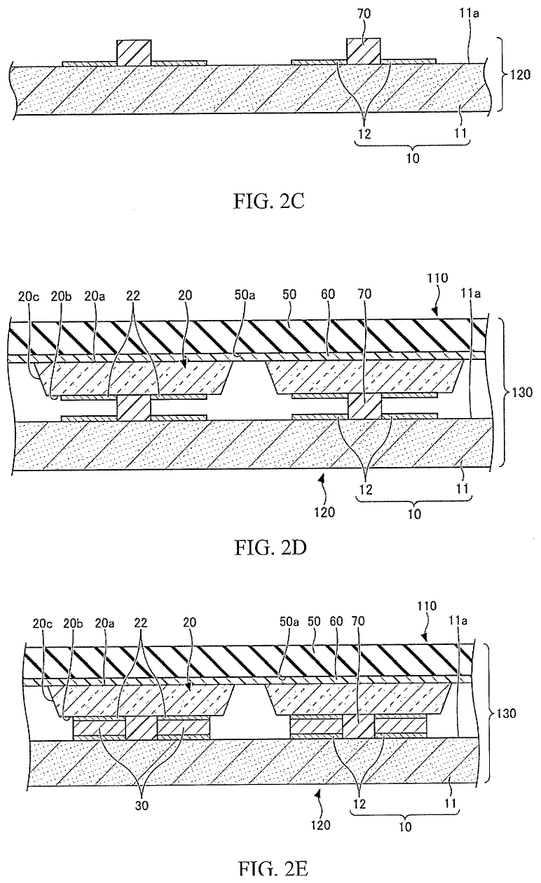

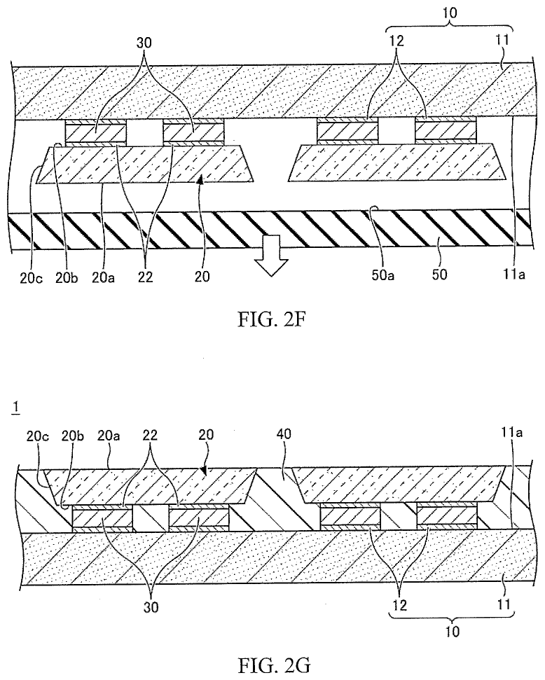

FIGS. 2A to 2G are views schematically illustrating an example of the manufacturing process of the method for manufacturing the light-emitting device according to the first embodiment. Specifically, FIG. 2B is a plan view illustrating a manufacturing step of the light-emitting device. FIG. 2A and FIGS. 2C to 2G are cross-sectional views illustrating the manufacturing steps of the light-emitting device. In the description of the manufacturing method, “providing” a member is not limited to manufacturing the member but includes obtaining the member such as purchasing the member or procuring the member.

### Step of Providing First Structure

First, as illustrated in FIG. 2A, a first structure 110 including a support substrate 50, a first bonding member 60 disposed on a surface 50a of the support substrate 50, and the plurality of light-emitting elements 20 each having the first surface 20a and the second surface 20b opposite to the first surface 20a is provided. In each of the light-emitting elements 20, the first surface 20a is in contact with the first bonding member 60 and the plurality of electrodes 22 are disposed on the second surface 20b side.

Specifically, for example, a glass substrate or the like is provided as the support substrate 50. Subsequently, a material to be the first bonding member 60 is disposed on the surface 50a of the support substrate 50. The first bonding member 60 can be disposed using, for example, a screen-printing method. The first bonding member 60 preferably has adhesiveness. When the first bonding member 60 has adhesiveness, the light-emitting elements 20 to be mounted later can be attached to and supported by the first bonding member 60.

Subsequently, the plurality of light-emitting elements 20 are provided, and then each of the light-emitting elements 20 is bonded to the first bonding member 60 such that the first surface 20a of each of the light-emitting elements 20 is in contact with the first bonding member 60 on the support substrate 50. For example, the light-emitting elements 20 whose number is in a range from 100 to 2000000 can be bonded to the first bonding member 60 in a matrix.

As the first bonding member 60, a material that can be dissolved in a predetermined solution can be used. Preferably, the first bonding member 60 has the above adhesiveness and chemical resistance to metal plating. Examples of the first bonding member 60 that can be used include phenolic-based resin, epoxy-based resin, silicone-based resin, and acrylic-based resin. The first bonding member 60 is, for example, a resist.

### Step of Providing Second Structure

Subsequently, as illustrated in FIGS. 2B and 2C, a second structure 120 is provided which includes the substrate 10 including the base member 11 and the plurality of terminal portions 12 disposed on the surface 11a of the base member 11, and a second bonding member 70 disposed between the plurality of terminal portions 12 on the surface 11a of the base member 11 and being thicker than each of the terminal portions 12. In FIG. 2B, for convenience, the base member 11 is illustrated without a dot pattern, the terminal portions 12 are illustrated with a high-density dot pattern, and the second bonding member 70 is illustrated with a low-density dot pattern. FIG. 2C is a cross-sectional view taken along line IIC-IIC in FIG. 2B.

Specifically, the substrate 10 including the base member 11 and the plurality of terminal portions 12 is provided. The substrate 10 can be provided, for example, by forming a plurality of pairs of terminal portions 12 on the surface 11a of the base member 11 having a flat plate shape, such as a silicon plate, by a plating method, a sputtering method, a vapor deposition method, or the like.

Subsequently, the second bonding member 70 that is disposed between the pair of terminal portions 12 and is thicker than the terminal portions 12 is formed on the surface 11a of the base member 11. Specifically, the second bonding member 70 having a planar size smaller than the planar size of the light-emitting element 20 in cross-sectional view is formed, in a region where the light-emitting element 20 is to be mounted, such that respective electrodes 22 of the light-emitting element 20 and respective terminal portions 12 of the substrate 10 can be spaced apart from each other while facing each other when the light-emitting element 20 is mounted later.

The second bonding member 70 can be formed using a photolithography method or a screen-printing method. A photolithography method is preferable in that a fine pattern can be formed. The second bonding member 70 preferably has adhesiveness. When the second bonding member 70 has adhesiveness, the light-emitting element 20 to be mounted later can be attached to and supported by the second bonding member 70.

As the second bonding member 70, a material that can be dissolved in a predetermined solution can be used. As the second bonding member 70, for example, a material appropriately selected from the materials exemplified as the first bonding member 60 can be used. For the second bonding member 70, a material that is the same as or different from the material of the first bonding member 60 may be used. For the second bonding member 70, a material that can be dissolved in the same solution as that of the first bonding member 60 is preferably selected. In this case, the second bonding member 70 can be dissolved simultaneously with the first bonding member 60, so that the manufacturing process can be simplified.

The cross-sectional shape of the second bonding member 70 may be rectangular or square. That is, a contact surface (upper surface) of the second bonding member 70 in contact with the light-emitting element 20 and a lateral surface of the second bonding member 70 can be substantially perpendicular to each other. This makes it possible to accurately secure a contact region between the light-emitting element 20 and the second bonding member 70 and a region where the conductive member 30 that connects the terminal portions 12 of the substrate 10 and the electrodes 22 of the light-emitting element 20 to each other later is disposed.

The cross-sectional shape of the second bonding member 70 may be tapered. The second bonding member 70 may have a shape that becomes wider from the surface 11a of the base member 11 toward the light-emitting elements 20, or a shape that becomes narrower from the surface 11a of the base member 11 toward the light-emitting elements 20. When the second bonding member 70 has a shape that becomes wider from the surface 11a of the base member 11 toward the light-emitting elements 20, the contact area between the light-emitting elements 20 and the second bonding member 70 can be increased, and the light-emitting elements 20 and the second bonding member 70 can be more reliably bonded to each other.

By forming the second bonding member 70 thicker than the terminal portions 12, when the light-emitting element 20 is mounted on the second bonding member 70 later, a respective one of the terminal portions 12 provided on the base member 11 and a respective one of the electrodes 22 of the light-emitting element 20 mounted on the second bonding member 70 can be spaced apart from each other with the second bonding member 70 located therebetween. The thickness of the second bonding member 70 can be, for example, in a range from 5 μm to 20 μm.

### Step of Disposing First Structure on Second Structure

Subsequently, as illustrated in FIG. 2D, the first structure 110 is disposed on the second bonding member 70 of the second structure 120 such that a respective one of the plurality of electrodes 22 and a respective one of the plurality of terminal portions 12 are spaced apart from each other while facing each other.

Specifically, first, the second structure 120 is disposed on a stage with the terminal portions 12 facing upward. Subsequently, the first structure 110 is disposed on the second structure 120 such that a respective one of the plurality of electrodes 22 face a respective one of the plurality of terminal portions 12. At this time, an upper surface of the second bonding member 70 is in contact with the second surface 20b located between adjacent electrodes 22 in each of the light-emitting elements 20. A part of the upper surface of the second bonding member 70 may cover an end portion of the electrodes 22. A respective one of the electrodes 22 of the light-emitting element 20 and a respective one of the terminal portions 12 of the substrate 10 are spaced apart from each other.

Subsequently, the light-emitting elements 20 and the substrate 10 disposed on the stage are heated at a predetermined temperature and pressurized. At this time, the light-emitting elements 20 and the substrate 10 are thermocompression-bonded to each other via the second bonding member 70 on the stage. That is, the second bonding member 70 is softened, and the light-emitting elements 20 and the substrate 10 are bonded to each other via the second bonding member 70 due to the adhesiveness of the second bonding member 70. Thus, a third structure 130 is obtained. The predetermined temperature is set to equal to or higher than the temperature at which the second bonding member 70 is softened. For example, when the temperature at which the second bonding member 70 is softened is 90° C., the predetermined temperature is preferably 95° C. or higher including a margin. The heating time at the predetermined temperature is preferably in a range from 1 minute to 1 hour, for example. By heating the light-emitting elements 20 and the substrate 10 under such conditions, the second bonding member 70 can be softened to such an extent that the second bonding member 70 exhibits adhesiveness.

### Step of Connecting Plurality of Electrodes and Plurality of Terminal Portions

Subsequently, as illustrated in FIG. 2E, respective ones of the plurality of electrodes 22 are connected to respective ones of the plurality of terminal portions 12. Specifically, for example, the conductive member 30 is formed by electrolytic plating or electroless plating to electrically connect a respective one of the electrodes 22 of the light-emitting element 20 and a respective one of the terminal portions 12 of the substrate 10. The conductive member 30 can be made of copper (Cu) or gold (Au), for example. The conductive member 30 may be made of zinc (Zn), chromium (Cr), nickel (Ni), and/or the like.

In addition to the function of supporting the light-emitting element 20, the second bonding member 70 has a function of a plating mask at the time of connecting the terminal portions 12 and the electrodes 22. Therefore, a plating mask need not be disposed again before this step, so that the number of steps can be reduced. When a plating mask is disposed in addition to the second bonding member 70, a process may be complicated such that, for example, a different solution is required when removing the plating mask. However, such a concern does not occur by allowing the second bonding member 70 to have two functions of the function of supporting the light-emitting element 20 and the function of a plating mask.

### Step of Separating off Support Substrate

Subsequently, as illustrated in FIG. 2F, the support substrate 50 is separated off from the plurality of light-emitting elements 20. For example, the first bonding member 60 and the second bonding member 70 are exposed to a solution to be removed, so that the support substrate 50 is separated off from the plurality of light-emitting elements 20. Specifically, for example, in a state in which the first structure 110 faces downward and the second structure 120 faces upward, the first bonding member 60 and the second bonding member 70 are immersed in the solution to be dissolved, which allows the support substrate 50 to drop downward. Alternatively, the support substrate 50 may be separated off by ejecting the solution to the first bonding member 60 and the second bonding member 70 by using a nozzle to dissolve the first bonding member 60 and the second bonding member 70.

The solution may be a mixed liquid containing sulfuric acid, an organic-based solvent, and the like. Examples of the organic-based solvent that can be used include at least one solvent selected from the group consisting of an alcohol-based solvent such as 2-propanol, a ketone-based solvent such as acetone, an ester-based solvent such as ethyl acetate, and an ether-based solvent.

### Step of Disposing Light Reflective Member

Subsequently, as illustrated in FIG. 2G, the light reflective member 40 is disposed on the substrate 10 as needed. For example, an uncured white resin covering the plurality of light-emitting elements 20 is disposed on the substrate 10, and is caused to flow so as to be deposited between lateral surfaces 20c, facing each other, of adjacent light-emitting elements 20 and between a respective one of the second surfaces 20b of the light-emitting elements 20 and the surface 11a of the base member 11. Subsequently, the white resin is cured to obtain the light reflective member 40. The uncured white resin can be disposed on the substrate 10 by, for example, potting, spraying, or printing. When the first surface 20a of the light-emitting element 20 is covered with the white resin, the first surface 20a is exposed by polishing or the like.

Through the above steps, the light-emitting device 1 in which the plurality of light-emitting elements 20 are mounted on the substrate 10 can be manufactured.

As described above, in the method for manufacturing the light-emitting device 1, the support substrate 50 is separated off from the plurality of light-emitting elements 20 after the step of connecting a respective one of the plurality of electrodes 22 and a respective one of the plurality of terminal portions 12. That is, when the support substrate 50 is separated off, the electrodes 22 of the light-emitting element 20 have already been connected to the terminal portions 12 of the substrate 10. Therefore, the light-emitting elements 20 are not removed together with the support substrate 50, and the support substrate 50 can be more reliably separated off from the light-emitting elements 20. In addition, the first bonding member 60 and the second bonding member 70 are exposed to a solution to be removed, so that the support substrate 50 can be separated off from the light-emitting elements 20 with a small number of steps.

In the step of separating off the support substrate 50, in a state in which the first structure 110 faces downward and the second structure 120 faces upward, the first bonding member 60 and the second bonding member 70 are immersed in a solution to be dissolved, which allows the support substrate 50 to drop. In this manner, the necessity of time and effort for picking up the support substrate 50 by using a suction jig or the like can be eliminated.

### Second to Fourth Embodiments

Second to fourth embodiments describe examples of a method for manufacturing the light-emitting device 1 different from that of the first embodiment.

### Manufacturing Method for Light-Emitting Device According to Second Embodiment

In the method for manufacturing the light-emitting device according to the second embodiment, in a step of providing a first structure, a plurality of first bonding members spaced apart from each other are disposed on the surface of a support substrate in correspondence with the positions of a plurality of light-emitting elements.

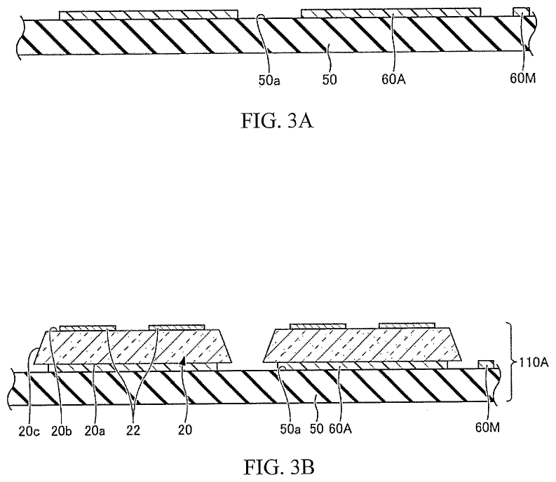

FIGS. 3A and 3B are cross-sectional views schematically illustrating an example of manufacturing steps of the method for manufacturing the light-emitting device according to the second embodiment.

FIGS. 3A and 3B illustrate steps of providing a first structure 110A. The first structure 110A is different from the first structure 110 in that a plurality of first bonding members 60A spaced apart from each other are employed in place of the one continuous first bonding member 60.

In order to provide the first structure 110A, first, as illustrated in FIG. 3A, the support substrate 50 is provided, and the plurality of first bonding members 60A spaced apart from each other are disposed on the surface 50a of the support substrate 50 in correspondence with the positions of the plurality of light-emitting elements 20. The plurality of first bonding members 60A can be disposed using, for example, a photolithography method or a screen-printing method.

In this step, an alignment mark 60M, which is to be used when the light-emitting elements 20 are disposed on the first bonding members 60A, may be deposited on the surface 50a of the support substrate 50 along with the first bonding members 60A using the same material as that of the first bonding member 60A. Any appropriate number of alignment marks 60M may be located at any appropriate positions, and, for example, when the surface 50a of the support substrate 50 has a rectangular shape in plan view, one set of alignment marks 60M can be disposed in a diagonal direction of the surface 50a. The alignment mark 60M can be, for example, cross-shaped in plan view.

Subsequently, as illustrated in FIG. 3B, after the plurality of light-emitting elements 20 are provided, the respective light-emitting elements 20 are bonded to the respective first bonding members 60A such that the respective first surfaces 20a of the light-emitting elements 20 are in contact with the respective first bonding members 60A on the support substrate 50. As the first bonding member 60A, for example, a material appropriately selected from the materials exemplified as those for the first bonding member 60 can be used. When each of the light-emitting elements 20 is disposed, each of the first bonding members 60A and a corresponding one of the light-emitting elements 20 can be accurately aligned by using the alignment mark 60M as a reference.

Subsequently, the same steps as those in FIGS. 2B to 2G of the first embodiment are performed, so that the light-emitting device 1 is obtained.

As described above, in the second embodiment, in the step of providing the first structure 110A, the plurality of first bonding members 60A spaced apart from each other are disposed on the surface 50a of the support substrate 50 in correspondence with the positions of the plurality of light-emitting elements 20. Thus, the amount of the first bonding members 60A can be made smaller than the amount of the first bonding members 60 in the first embodiment. As a result, the time required to remove the first bonding members 60A and the second bonding member 70 can be made shorter than the time required to remove the first bonding member 60 and the second bonding member 70 in the first embodiment. In addition, the amount of residue generated when the first bonding members 60A are removed can be reduced.

In plan view, the size of each of the plurality of first bonding members 60A is preferably smaller than that of the first surface 20a of the light-emitting element 20. Thus, the above effect becomes more remarkable.

In the step of disposing the plurality of first bonding members 60A, by disposing the alignment mark 60M using the same material as that of the first bonding members 60A, a step of separately disposing an alignment mark is not necessary, and thus the manufacturing process can be simplified.

### Manufacturing Method for Light-Emitting Device According to Third Embodiment

The method for manufacturing a light-emitting device according to the third embodiment further includes a step of disposing a third bonding member covering at least a part of the light-emitting elements on the first bonding member between the step of providing the first structure and the step of disposing the first structure on the second bonding member, and a step of processing the third bonding member to form a wall between the light-emitting elements between the step of disposing the third bonding member and the connecting step, and in the separating step, the first bonding member, the second bonding member, and the third bonding member are exposed to a solution to be removed.

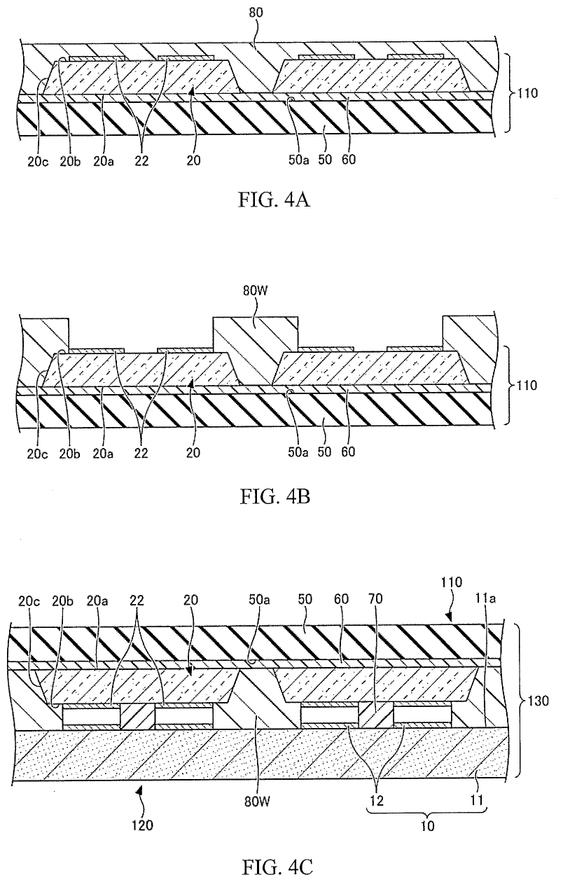

FIGS. 4A to 4C are cross-sectional views schematically illustrating an example of manufacturing steps of the method for manufacturing the light-emitting device according to the third embodiment.

First, the step of providing the first structure 110 of the first embodiment illustrated in FIG. 2A is performed. Subsequently, as illustrated in FIG. 4A, a third bonding member 80 covering at least a part of the light-emitting elements 20 is disposed on the first bonding member 60 of the first structure 110. The third bonding member 80 may be formed thicker than the light-emitting elements 20 to cover the entire light-emitting elements 20. The third bonding member 80 can be disposed by a screen-printing method, for example.

As the third bonding member 80, a material that can be dissolved in a predetermined solution can be used. As the third bonding member 80, for example, a material appropriately selected from the materials exemplified as those for the first bonding member 60 can be used. For the third bonding member 80, a material that is the same as or different from that of the first bonding member 60 may be used. For the third bonding member 80, a material that can be dissolved in the same solution as that of the first bonding member 60 and the second bonding member 70 is preferably selected. In this case, the third bonding member 80 can be dissolved simultaneously with the first bonding member 60 and the second bonding member 70, so that the manufacturing process can be simplified.

Subsequently, as illustrated in FIG. 4B, the third bonding member 80 is processed to form a wall 80W between the light-emitting elements 20. The wall 80W can be formed by, for example, removing an unnecessary portions of the third bonding member 80 by etching. The steps described with reference to FIGS. 4A and 4B can be performed between the step of providing the first structure 110 and the step of disposing the first structure 110 on the second bonding member 70 of the second structure 120.

Subsequently, as illustrated in FIG. 4C, the first structure 110 is disposed on the second bonding member 70 of the second structure 120 such that a respective one of the plurality of electrodes 22 and a respective one of the plurality of terminal portions 12 are spaced apart from each other while facing each other, thereby forming the third structure 130. A specific process of arranging is as described with reference to FIG. 2D. In this step, for example, a space surrounded by the terminal portion 12, the electrode 22, the second bonding member 70, and the wall 80W is formed. This space is a region where the conductive member 30 is to be formed.

Subsequently, the same steps as those in FIGS. 2E to 2G of the first embodiment are performed, so that the light-emitting device 1 is obtained. However, in the present embodiment, in the step of separating off the support substrate 50 described with reference to FIG. 2F, the first bonding member 60, the second bonding member 70, and the third bonding member 80 are exposed to a solution to be removed.

As described above, in the third embodiment, the third bonding member 80 covering at least a part of the light-emitting elements 20 is disposed on the first bonding member 60 and is further processed to form the wall 80W between the light-emitting elements 20. Thus, in the step of connecting the plurality of electrodes 22 and the plurality of terminal portions 12, short-circuiting of the electrodes 22 between adjacent light-emitting elements 20 can be prevented.

In the step of separating off the support substrate 50, the first bonding member 60, the second bonding member 70, and the third bonding member 80 are exposed to a solution to be removed. Accordingly, when a material that can be dissolved in the same solution as that of the first bonding member 60 and the second bonding member 70 is selected as the third bonding member 80, the third bonding member 80 can be removed without providing an additional step for that.

### Method for Manufacturing Light-Emitting Device According to Fourth Embodiment

In the method for manufacturing a light-emitting device according to the fourth embodiment, the step of providing the first structure includes a step of temporarily fixing the second surface sides of the plurality of light-emitting elements to a surface of a transparent substrate via a sacrificial layer, a step of disposing the transparent substrate to which the light-emitting elements are temporarily fixed on the support substrate with the first bonding member disposed on a surface thereof, such that the first bonding member and the plurality of light-emitting elements face each other, and a step of irradiating the sacrificial layer with laser light via the transparent substrate to transfer the sacrificial layer and the plurality of light-emitting elements onto the first bonding member.

The method for manufacturing a light-emitting device according to the fourth embodiment may include a step of disposing, on the first bonding member, a fourth bonding member covering at least a part of the light-emitting elements after the step of transferring the plurality of light-emitting elements and between the step of providing the first structure and the step of disposing the first structure on the second bonding member; a step of removing the sacrificial layer after the step of disposing the fourth bonding member; and a step of removing the fourth bonding member between the step of removing the sacrificial layer and the step of disposing the first structure on the second bonding member.

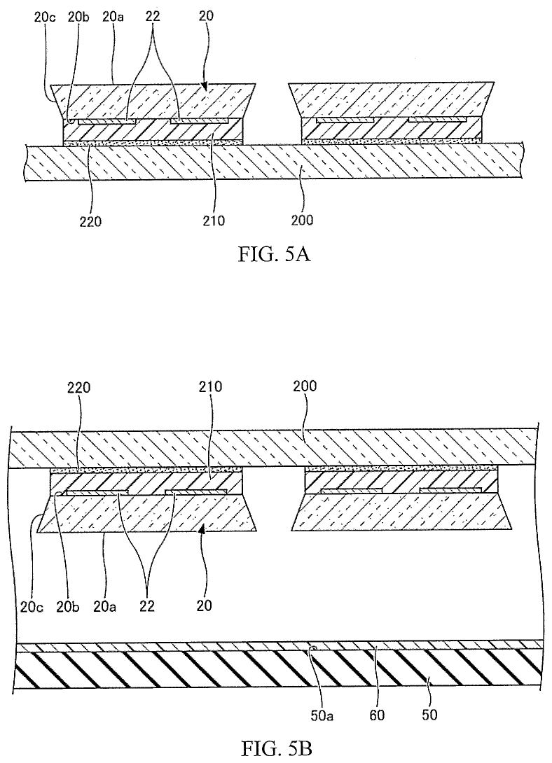

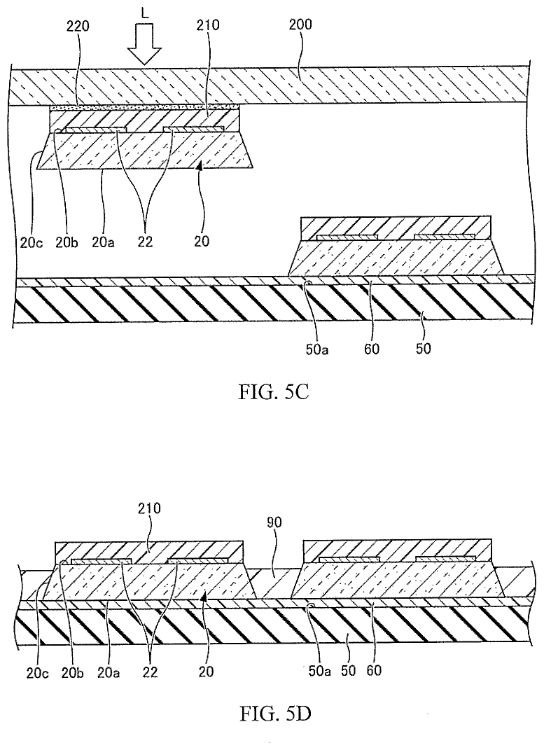

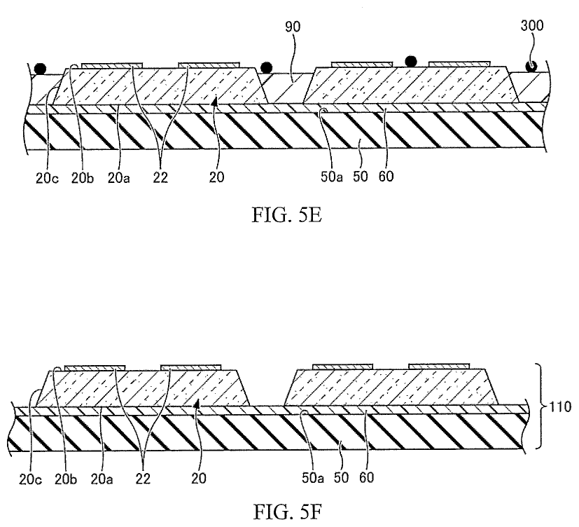

FIGS. 5A to 5F are cross-sectional views schematically illustrating an example of manufacturing steps of the method for manufacturing a light-emitting device according to the fourth embodiment. FIGS. 5A to 5C illustrate a part of the step of providing the first structure.

First, as illustrated in FIG. 5A, after a transparent substrate 200 is provided, the second surface 20b sides of the plurality of light-emitting elements 20 are temporarily fixed to a surface of the transparent substrate 200 via a sacrificial layer 210. A release layer 220 is provided between the surface of the transparent substrate 200 and the sacrificial layer 210. The electrodes 22 of the plurality of light-emitting elements 20 are covered with the sacrificial layer 210.

For the transparent substrate 200, any appropriate material can be used as long as it has a certain transmittance or more with respect to laser light to be described below; for example, sapphire, glass, silicon, or the like can be used. Examples of the material of the sacrificial layer 210 include a material containing, as a main component, a thermosetting resin such as a silicone resin, a silicone-modified resin, an epoxy resin, or a phenol resin, or a thermoplastic resin such as a polycarbonate resin, an acrylic resin, a methylpentene resin, or a polynorbornene resin. For the release layer 220, any appropriate material may be used as long as it disappears by irradiation with laser light to be described below; a material containing an epoxy resin, an acrylic resin, or a polyimide resin as a main component can be used and for example, a mixture of a fluorene-based monomer and propylene glycol monomethyl ether acetate (PGMAE) can be used. Examples of the laser light that can be used include light having a light emission peak wavelength in a wavelength range from 250 nm to 400 nm.

Subsequently, as illustrated in FIG. 5B, the support substrate 50 having the surface 50a on which the first bonding member 60 is disposed is provided, and the transparent substrate 200 to which the plurality of light-emitting elements 20 are temporarily fixed is disposed such that the first bonding member 60 and the plurality of light-emitting elements 20 face each other.

Subsequently, as illustrated in FIG. 5C, the sacrificial layer 210 and the release layer 220 are irradiated with laser light L via the transparent substrate 200. Thus, the release layer 220 disappears, and the sacrificial layer 210 and the plurality of light-emitting elements 20 can be transferred onto the first bonding member 60. In FIG. 5C, the light-emitting element 20 and the sacrificial layer 210 located on the right side have already been transferred onto the first bonding member 60, and the light-emitting element 20 and the sacrificial layer 210 located on the left side are to be transferred onto the first bonding member 60 by irradiation with the laser light L.

Subsequently, as illustrated in FIG. 5D, a fourth bonding member 90 covering at least a part of each of the light-emitting elements 20 is disposed on the first bonding member 60. In this step, the fourth bonding member 90 is preferably arranged without reaching the plurality of electrodes 22 of the light-emitting element 20. That is, the sacrificial layer 210 is preferably exposed from the fourth bonding member 90. This step is performed after the step of transferring the plurality of light-emitting elements 20 and between the step of providing the first structure and the step of disposing the first structure on the second bonding member of the second structure.

As the fourth bonding member 90, a material that can be dissolved in a predetermined solution can be used. As the fourth bonding member 90, for example, a material appropriately selected from the materials exemplified as that of the first bonding member 60 can be used. For the fourth bonding member 90, a material that is the same as or different from that of the first bonding member 60 may be used. For the fourth bonding member 90, a material that can be dissolved in a solution different from that of the first bonding member 60 is preferably selected. In this case, in FIG. 5F to be described below, the fourth bonding member 90 can be selectively dissolved without dissolving the first bonding member 60.

Subsequently, as illustrated in FIG. 5E, the sacrificial layer 210 is removed. The sacrificial layer 210 can be removed by, for example, reactive ion etching (RIE). When removing the sacrificial layer 210, the electrodes 22 and the fourth bonding member 90 are partially etched, which may cause foreign matters 300 such as gold nanoparticles or resin pieces to adhere to a surface of the fourth bonding member 90.

Subsequently, as illustrated in FIG. 5F, the fourth bonding member 90 is selectively removed without removing the first bonding member 60. Thus, the first structure 110 is obtained. The fourth bonding member 90 can be removed by being exposed to a predetermined solution. By removing the fourth bonding member 90, the foreign matters 300 can also be removed at the same time.

Subsequently, the same steps as those in FIGS. 2B to 2G of the first embodiment are performed, so that the light-emitting device 1 is obtained.

As described above, the fourth embodiment includes, after the sacrificial layer 210 and the plurality of light-emitting elements 20 are transferred onto the first bonding member 60, a step of disposing, on the first bonding member 60, the fourth bonding member 90 covering at least a part of the light-emitting elements 20. After the step of disposing the fourth bonding member 90, the sacrificial layer 210 is removed, and then the fourth bonding member 90 is removed. When the fourth bonding member 90 is removed, the foreign matters 300 are also removed at the same time. Therefore, when a respective one of the electrodes 22 of the light-emitting element 20 and a respective one of the terminal portions 12 of the substrate 10 are connected to each other, abnormal precipitation or the like of plating depending on the presence of the foreign matters 300 can be inhibited.

While certain embodiments and the like have been described in detail above, the disclosure is not limited to the above-described embodiments and the like, various modifications and substitutions can be made to the above-described embodiments and the like without departing from the scope described in the claims.

### REFERENCE SIGNS LIST

1 Light-emitting device
10 Substrate
11 Base member
11a Surface
12 Terminal portion
20 Light-emitting element
20a First surface
20b Second surface
20c Lateral surface
22 Electrode
30 Conductive member
40 Light reflective member
50 Support substrate
50a Surface
60, 60A First bonding member
60M Alignment mark
70 Second bonding member
80 Third bonding member
80W Wall
90 Fourth bonding member
110, 110A First structure
120 Second structure
130 Third structure
200 Transparent substrate
210 Sacrificial layer
220 Release layer
300 Foreign matter

What is claimed is:

1. A method for manufacturing a light-emitting device, the method comprising:
providing a first structure comprising
a support substrate,
a first bonding member disposed on a surface of the support substrate, and
a plurality of light-emitting elements each having a first surface and a second surface opposite to the first surface, the first surface being in contact with the first bonding member, each of the light-emitting elements comprising a plurality of electrodes on a second surface side;
providing a second structure comprising
a substrate comprising a base member and a plurality of terminal portions disposed on a surface of the base member, and
a second bonding member being disposed between the plurality of terminal portions on the surface of the base member and being thicker than each of the terminal portions;
disposing the first structure on the second bonding member of the second structure such that a respective one of the plurality of electrodes and a respective one of the plurality of terminal portions are spaced apart from each other while facing each other;
connecting the respective one of the plurality of electrodes and the respective one of the plurality of terminal portions; and
after the connecting, exposing the first bonding member and the second bonding member to a solution to remove the first bonding member and the second bonding member to separate off the support substrate from the plurality of light-emitting elements.

2. The method for manufacturing a light-emitting device, according to claim 1, wherein, in the separating, in a state in which the first structure faces downward and the second structure faces upward, the first bonding member and the second bonding member are immersed in a solution to be dissolved, which allows the support substrate to drop.

3. The method for manufacturing a light-emitting device, according to claim 1, wherein, in the providing of the first structure, a plurality of the first bonding members spaced apart from each other are disposed on the surface of the support substrate in correspondence with positions of the plurality of light-emitting elements.

4. The method for manufacturing a light-emitting device, according to claim 3, wherein in plan view, a size of each of the plurality of first bonding members is smaller than a size of the first surface of each of the light-emitting elements.

5. The method for manufacturing a light-emitting device, according to claim 3, wherein, the providing of the first structure comprises depositing an alignment mark, which is to be used when the light-emitting elements are disposed on the first bonding members, on the surface of the support substrate along with the first bonding members using a material that is the same as a material of the first bonding members.

6. The method for manufacturing a light-emitting device, according to claim 1, further comprising:
disposing, on the first bonding member, a third bonding member covering at least a part of the light-emitting elements between the providing of the first structure and the disposing of the first structure on the second bonding member; and
between the disposing of the third bonding member and the connecting, processing the third bonding member to form a wall between the light-emitting elements,
wherein in the separating, the first bonding member, the second bonding member, and the third bonding member are exposed to a solution to be removed.

7. The method for manufacturing a light-emitting device, according to claim 1, wherein the providing of the first structure comprises:
temporarily fixing a side of the second surface of each of the plurality of light-emitting elements to a surface of a transparent substrate via a sacrificial layer;
disposing the transparent substrate, to which the light-emitting elements have been temporarily fixed, on the support substrate with the first bonding member disposed on the surface of the support substrate, such that the first bonding member and the plurality of light-emitting elements face each other; and
transferring the sacrificial layer and the plurality of light-emitting elements onto the first bonding member by irradiating the sacrificial layer with laser light via the transparent substrate.

8. The method for manufacturing a light-emitting device, according to claim 7, further comprising:
after the transferring of the plurality of light-emitting elements and between the providing of the first structure and the disposing of the first structure on the second bonding member, disposing, on the first bonding member, a fourth bonding member covering at least a part of the light-emitting elements;
removing the sacrificial layer after the disposing of the fourth bonding member; and
between the removing of the sacrificial layer and the disposing of the first structure on the second bonding member, removing the fourth bonding member.

9. The method for manufacturing a light-emitting device, according to claim 8, wherein, in the disposing of the fourth bonding member, the fourth bonding member is disposed such that the fourth bonding member does not reach the plurality of electrodes.

10. The method for manufacturing a light-emitting device, according to claim 2, wherein, in the providing of the first structure, a plurality of the first bonding members spaced apart from each other are disposed on the surface of the support substrate in correspondence with positions of the plurality of light-emitting elements.

11. The method for manufacturing a light-emitting device, according to claim 10, wherein in plan view, a size of each of the plurality of first bonding members is smaller than a size of the first surface of each of the light-emitting elements.

12. The method for manufacturing a light-emitting device, according to claim 10, wherein, the providing of the first structure comprises depositing an alignment mark, which is to be used when the light-emitting elements are disposed on the first bonding members, on the surface of the support substrate along with the first bonding members using a material that is the same as a material of the first bonding members.

13. The method for manufacturing a light-emitting device, according to claim 2, further comprising:
disposing, on the first bonding member, a third bonding member covering at least a part of the light-emitting elements between the providing of the first structure and the disposing of the first structure on the second bonding member; and
between the disposing of the third bonding member and the connecting, processing the third bonding member to form a wall between the light-emitting elements,
wherein in the separating, the first bonding member, the second bonding member, and the third bonding member are exposed to a solution to be removed.

14. The method for manufacturing a light-emitting device, according to claim 2, wherein the providing of the first structure comprises:
temporarily fixing a side of the second surface of each of the plurality of light-emitting elements to a surface of a transparent substrate via a sacrificial layer;
disposing the transparent substrate, to which the light-emitting elements have been temporarily fixed, on the support substrate with the first bonding member disposed on the surface of the support substrate, such that the first bonding member and the plurality of light-emitting elements face each other; and
transferring the sacrificial layer and the plurality of light-emitting elements onto the first bonding member by irradiating the sacrificial layer with laser light via the transparent substrate.

15. The method for manufacturing a light-emitting device, according to claim 14, further comprising:
after the transferring of the plurality of light-emitting elements and between the providing of the first structure and the disposing of the first structure on the second bonding member, disposing, on the first bonding member, a fourth bonding member covering at least a part of the light-emitting elements;
removing the sacrificial layer after the disposing of the fourth bonding member; and
between the removing of the sacrificial layer and the disposing of the first structure on the second bonding member, removing the fourth bonding member.

16. The method for manufacturing a light-emitting device, according to claim 15, wherein, in the disposing of the fourth bonding member, the fourth bonding member is disposed such that the fourth bonding member does not reach the plurality of electrodes.
